(19) United States
(12) Patent Application Publication
(10) Pub. No.: US 2008/0099798 A1
(43) Pub. Date: May 1, 2008

(54) Methods and devices for amplifying a signal

(76) Inventor: Douglas Kerns, Sierra Madre, CA (US)

Correspondence Address: Darryl G. Walker, Suite 235, 300 South First Street, San Jose, CA, 95113, US

(21) Appl. No.: 11/906,683

(22) Filed: Oct. 3, 2007

Related U.S. Application Data
(60) Provisional application No. 60/855,383, filed on Oct. 31, 2006.

(51) Int. Cl. H01L 29/808

(52) U.S. Cl. 257/272; 257/E29.312

(57) ABSTRACT

A junction field effect transistor (JFET) device is disclosed for amplifying an input signal. The JFET device includes a first gate region and a substrate/well/bulk region that may form a second gate region. The JFET device also includes a first source/drain region and a second source/drain region. The first source/drain region may receive an input signal and either the first gate region or the second gate region may provide an amplified output signal. A current supplied across the channel region may be substantially independent of a current supplied between the gate region and a bulk region of the substrate. The device may be configured to amplify a time varying input signal to provide an amplified time varying output signal.

This application claims the benefit of U.S. Provisional Patent Application Ser. No. 60/855,383, filed Oct. 31, 2006, the contents of which are incorporated by reference herein.

### TECHNICAL FIELD

The present invention relates generally to semiconductor devices, and more particularly to a method and device for amplifying a signal using a junction field effect transistor (JFET) configured as a bipolar junction transistor (BJT).

### BACKGROUND OF THE INVENTION

Devices for amplifying a signal are included in many electronic circuits, including both analog and digital circuits. In circuits where amplification is provided, it is often desirable to provide some degree of gain control for the amplification. As reference herein, gain control can include both positive gain control and negative gain control (i.e., amplitude attenuation).

Known amplification and gain control devices and circuit designs often receive input signals represented as voltage inputs. There is a trend toward reducing power supply voltages in an effort to reduce power consumption of microcircuits. Also, as feature sizes reduce, it can be desirable to reduce power supply voltages to improve the electrical integrity of the circuits. Such a reduction in feature size can involve an associated scaling of any amplifier circuits to accommodate the reduced voltages.

### SUMMARY OF THE INVENTION

A device is disclosed for amplifying a signal, comprising: a gate region and a substrate, wherein the gate region is configured as one of an input and/or output for a time varying signal. A channel region may be provided to connect a source region and a drain region of the transistor device receiving or producing a time varying signal at a first location. A current may be supplied across the channel region and may be substantially independent of a current supplied between a gate region and a bulk region of the substrate. The device may be configured to amplify the time varying input signal to provide an amplified time varying output signal.

According to the embodiments, a circuit device for amplifying a signal is disclosed. The circuit device may include a junction field effect transistor (JFET) device having a gate region, a channel region, and a substrate. A current across the channel region may be substantially independent of the current between the gate region and the bulk region of the substrate. The circuit device may include a signal input circuit and a signal output circuit.

According to the embodiments, a method for amplifying a time varying input signal is also disclosed. The method may include establishing a transistor device having a gate region and a substrate, establishing a channel region that connects a source region and a drain region of the transistor device. A current supplied across the channel region may be substantially independent of a current supplied between the gate region and a bulk region of the substrate. The method may include amplifying an input signal supplied to the transistor device to provide an amplified signal at an output of the transistor device.

According to the embodiments, a method for establishing a circuit design is disclosed. The method may include creating a library of modular circuit components. A least one of the circuit components may be a JFET device having a gate region, a channel region, and a substrate. A current supplied across the channel region may be substantially independent of a current supplied between the gate region and a bulk region of the substrate. The method may include selecting the circuit component for inclusion in an electrical circuit, such that a time varying input signal is applied to a first contact of the JFET device. A second contact of the JFET device may provide a signal output which represents an amplified time varying input signal.

According to the embodiments, an amplifier circuit may include a JFET device that may be configured to amplify an input signal. The JFET device may include a first source/drain region coupled to receive an input signal and a second source/drain region coupled to receive a first potential. A first gate region of the JFET device may be coupled to provide an amplified output signal.

According to the embodiments the amplifier circuit may include a current source having a first current source terminal coupled to the first source/drain region and a second current source terminal coupled to receive a second potential.

According to the embodiments, the JFET device may operate as a bipolar junction transistor (BJT).

According to the embodiments, a method of amplifying an input signal may include receiving an input signal at a first source/drain region of a JFET and providing an amplified output signal at a first gate region of the JFET.

### BRIEF DESCRIPTION OF THE DRAWINGS

FIG. 1A is a cross sectional diagram of an n-channel junction field effect transistor (JFET) device that may be used in an amplifier circuit according to an embodiment.

FIG. 1B is a cross sectional diagram of a p-channel junction field effect transistor (JFET) device that may be used in an amplifier circuit according to an embodiment.

FIG. 1C is a cross sectional diagram of an n-channel junction field effect transistor (JFET) device that may be used in an amplifier circuit according to an embodiment.

FIG. 1D is a cross sectional diagram of a p-channel junction field effect transistor (JFET) device that may be used in an amplifier circuit according to an embodiment.

FIG. 2A is a circuit schematic diagram of an amplifier circuit according to an embodiment.

FIG. 2B is a circuit schematic diagram of an amplifier circuit according to an embodiment.

FIG. 3A is a circuit schematic diagram of an amplifier circuit according to an embodiment.

FIG. 3B is a circuit schematic diagram of an amplifier circuit according to an embodiment.

FIG. 4 is a graph of representative signals of an exemplary amplifier circuit operated in a current mode as a current-mode amplifier according to an embodiment

### DETAILED DESCRIPTION OF THE EMBODIMENTS

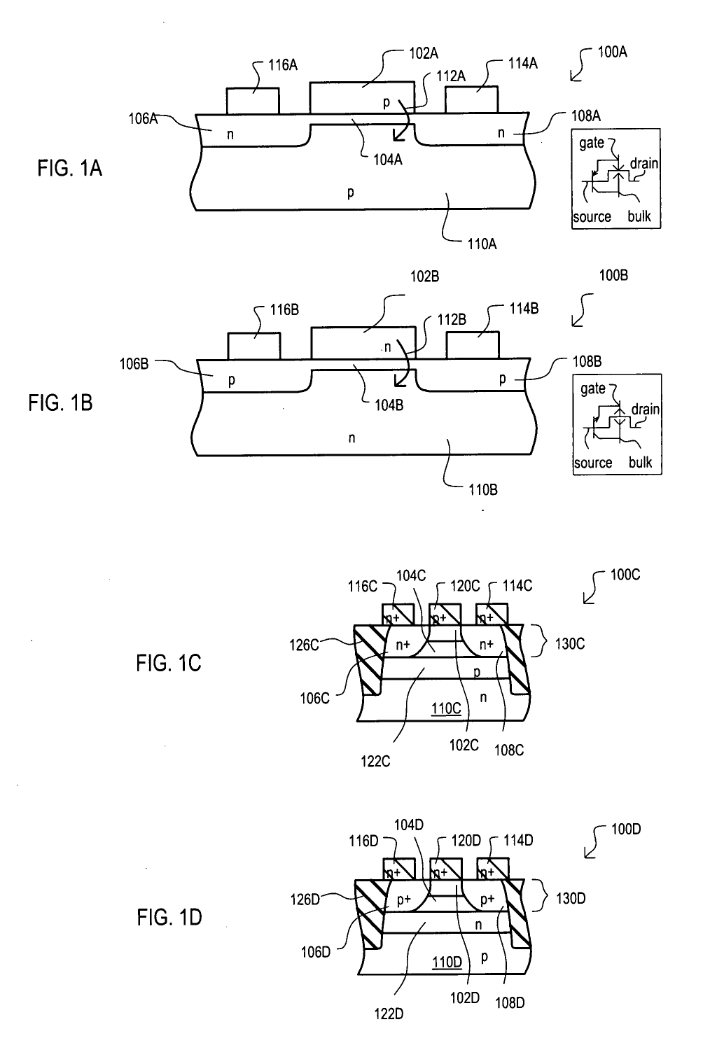

FIG. 1A illustrates a cross-sectional view of an exemplary junction field effect transistor (JFET) transistor device 100A configured for amplifying an input signal. The JFET 100A includes a gate region 102A and a substrate 110A, wherein the gate region may be configured as one of an input or an output for a time varying signal. The gate region 102A can be configured, for example, of p-type conductivity material.

The JFET device 100A may include a channel region 104A connecting a source region 106A and a drain region 108A of the transistor device. The channel region 104A may receive and/or produce a time varying signal at a first location. In the exemplary FIG. 1 device, a current supplied across the channel region 104 may be substantially independent of a current supplied between a gate region 102A and a bulk region/substrate 110A. That is, a drain to source current I_{DS} may be substantially independent of a current I_{GB}. The JFET device 100A can be thereby configured to amplify a time varying input signal to provide an amplified time varying output signal.

As reference herein, the phrase “substantially independent” means that the current flowing across the channel region 104A (e.g., from the drain region 108A to the source region 106A) does not significantly interact with current flowing between the gate region 102A and the bulk/substrate region 110A so as to significantly affect one another. The current flowing across the channel region 104A versus the current flowing from the gate region 102A to the bulk/substrate region 110A may thereby be considered electrically perpendicular. In the exemplary embodiment of FIG. 1A, these current paths also happen to be geometrically perpendicular.

The JFET device 100A as configured in accordance with exemplary embodiments described herein may function in two modes of operation. The JFET device 100A may function as both a bipolar junction transistor (BJT) and as a JFET simultaneously. In this way substantially independent currents that are essentially electrically perpendicular may be provided. Those skilled in the art will appreciate the aforementioned reference to the geometrical perpendicularity of the JFET device of FIG. 1 is by way of example only. That is, off angle configurations of the channel region 104A relative to a path from the gate to the bulk/substrate region 110A may be implemented and are encompassed by exemplary embodiments described herein.

The substantial independence of the two electrically perpendicular current paths is reflected in the following equations:

Bipolar Function: Gate-Bulk Current (I_{GB}):

I_{GB}=I₀exp(V_{GS}/U_{T})

JFET Function: Drain-Source Current (I_{DS}):

(Triode region, where V_{DS} is small) I_{DS}=βV_{DS}(V_{GS}−V_{T})

(saturation, where V_{DS} is large) I_{DS}=β(V_{GS}V_{T})²

In the foregoing equations, U_{T} is a scale factor which depends on device temperature. The value U_{T} has been referenced in other literature as a value “V_{T}”. See for example, Paul R. Gray, Paul J. Hurst, Stephen H. Lewis, Robert G. Meyer. Analysis and Design of Analog integrated Circuits 4^{th} Edition, John Wiley and Sons Inc., New York, N.Y. 2001.

As reference herein:

U_{T}=kT/electronic charge, where k is Boltzmann's constant and T is absolute temperature.

In the foregoing equations “U_{T}” is distinguished from the scale factors labeled I₀ and V_{T}. That is, in the foregoing equations, I₀ and V_{T} are scale factors which depend on the fabrication process. β is a scale factor which depends both on the fabrication process and on the geometric design of the JFET device 100A.

The foregoing equation for I_{DS} assumes the transistor is operating in saturation. In addition, where the drain voltage and the source voltage are approximately equal, the channel can be considered to function as a resistor in its behavior. Because the channel current I_{DS} is substantially independent of the gate to bulk current I_{GB}, the currents can be independently controllable. However, both will operate in dependence on the gate to source voltage V_{GS}. The currents of the FIG. 1A example can thereby be controlled as a function of V_{GS}. As such, application of a positive bias voltage to, for example, the source region of FIG. 1A can be used to control a gain of the amplifier device. That is, a change in the bias voltage can change a gain of the device.

In an exemplary circuit device where an electrical power supply voltage is relatively small, signal values can be represented as currents rather than as voltages. A current input can be amplified using the exemplary JFET device 100A of FIG. 1A. The FIG. 1A transistor device (JFET device 100A) may operate as a current-mode signal amplifier supporting two perpendicular current paths wherein a magnitude of one current can strongly influence the magnitude of the other to provide the amplification feature described herein.

In the embodiment of FIG. 1A, the gate region 102A may be configured, for example, of p-type conductivity material. The channel region 104A may connect the source region 106A and the drain region 108A of the transistor device (JFET device 100A.) In the exemplary embodiment of FIG. 1A, the channel region 106A may be formed as an n-type channel of n-type conductivity material.

In the exemplary embodiment of FIG. 1A, the gate region 102A may join the channel region 104A through a p-n junction, such that charge carriers can be injected into the channel region 104A through the gate region 102A provided a suitable voltage difference exists between the gate and channel regions. The arrow 112A in FIG. 1 schematically illustrates the trajectory of a positive charge carrier from the gate region 102A into the channel region 104A, and then on to a p-type bulk/substrate region 110A on the other side of the channel region 104A.

The movement of charge carriers into the p-type bulk/substrate region 110A constitutes an electrical current, referred to herein as a “BJT current”, described by the foregoing equation for I_{GB}. The current is analogous to the collector current of a bipolar junction transistor. The BJT current I_{GB} from the gate region 102A can be controlled by a voltage difference between the gate region 102A and the channel region 104A (e.g., the gate-to-source voltage V_{GS}) and possesses a strong non-linear function to this voltage difference. Given the strong non-linear dependence, a voltage between the gate region 102A and a source region 106A of the JFET device 100A may dominate control for the BJT current I_{GB}.

The JFET gate to source voltage V_{GS} depends primarily on the JFET channel current I_{DS}. The dependency, can, in an exemplary embodiment, be a relatively weak, non-linear function.

In accordance with exemplary embodiments, the JFET device 100A may include a first contact 114A that can receive an amplifier input signal. In this way, a drain region 108A can provide the amplifier input signal to the channel region 104A. It should be understood that the drain region 108A and source region 106A may be interchanged. Thus, the amplifier input signal may be provided to the source region 106A. The amplifier input signal may be a time varying input signal and can be a digital signal or it may be an analog signal.

JFET device 100A may include a second contact 116A connected to the source region 106A for receiving a bias voltage. In this way, the bias voltage may be applied to the channel region 104A through the second contact 116A and source region 106A. Of course, when the bias voltage is applied through the drain region 108A, the source region may receive the amplifier input signal. In exemplary embodiments, the output signal may represent an amplified version of the time varying input signal wherein the amount of amplification may be a function of the bias voltage received.

FIG. 1A includes an inset that illustrates an exemplary approximate equivalent circuit for the n-channel JFET device 100A.

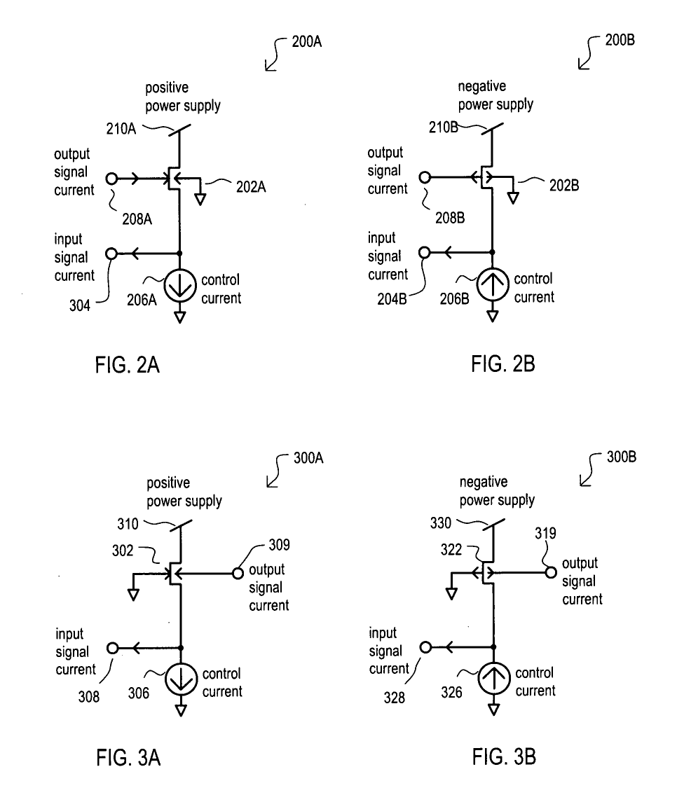

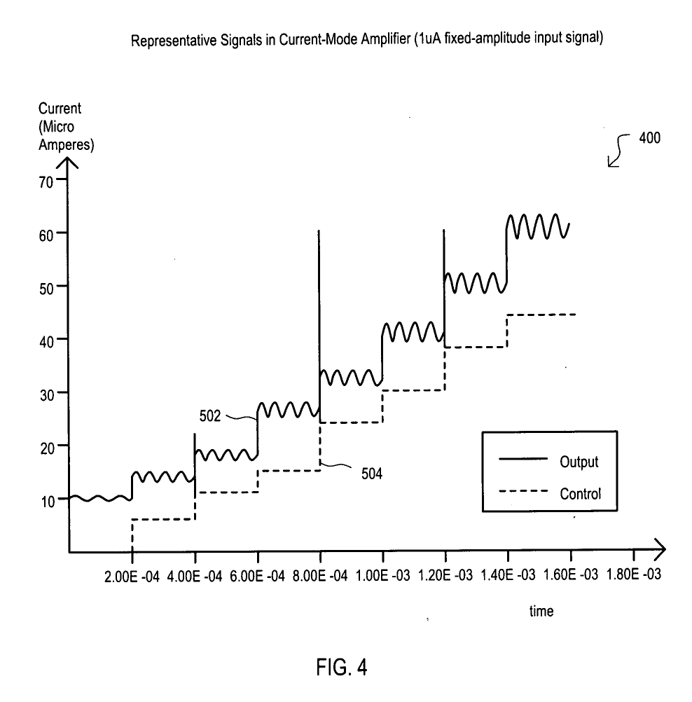

As described herein, the gate region 102A may provide an amplified time varying signal as an output signal. The gate region may include a gate contact that receives the output signal. Alternately, an output signal may be provided from a bulk region (in particular when the bulk is isolated from other circuitry to function essentially as a second gate region or a back gate region). However, when the output signal is provided at gate region 102A, the bulk may be placed at a reference potential (for example, a ground potential) as will be illustrated further in embodiments of FIGS. 2A, 2B, 3A, and 3B. Alternatively, when the output signal is provided from the bulk region, the gate region 102A may receive the reference potential, such as a ground potential) as will be illustrated further in the embodiments of FIGS. 4A and 4B.

In the embodiment of FIG. 1A, an exemplary voltage at the drain region 108A can be on the order of 300 to 600 millivolts. The bulk region 110A may be grounded, and the gate region 102A may be placed at a voltage on the order of 500 to 800 millivolts (a d.c. offset), for example. Of course, the voltages values are by way of example only and can be any suitable values selected by a circuit designer.

The ability to provide an output current signal from the gate region 102A that is related to the magnitude of an input signal applied to the source region 106A results from the JFET device 100A simultaneously performing the functions of two different electronic components (a JFET and a BJT). The JFET device 100A can function with a current in a source-to-drain direction across the channel region 104A as a JFET, but can function with a current in the gate to source direction as a bipolar junction transistor (BJT). Current flow across the gate region 102A and bulk/substrate region 110A may be controlled as a function of the voltage (or current) associated with the time varying input signal in conjunction with the bias voltage applied to the channel region 104A.

Because the gate region 102A and the bulk/substrate region 110A each interface with the channel region 104A via a p-n junction, the channel region 104A may present a barrier to charge carriers from the gate region 102A crossing to the bulk/substrate region 110A. This structure of the two regions separated by two p-n junctions may functionally establish a BJT with the channel region 104A being a barrier to charge movement due to the voltage between the gate region 102A and the channel region 104A. Charges that flow between the gate region 102A and the bulk/substrate region 110A do not substantially combine with charges that flow across the channel region 104A (between the drain region 108A and source region 106A), such that the resultant currents associated with the flow of charge may remain substantially independent. For example, charges comprising holes passing between the gate region 102A and the bulk/substrate region 110A may not appreciably combine with charges comprising electrons passing between the drain region 108A and the source region 106A.

The current (I_{DS}) passing between the drain region 108A and the source region 106A across the channel region 104A can change the channel voltage (e.g., gate-to-source voltage V_{GS}) which changes the height of the charge barrier between the gate region 102A and bulk/substrate region 110A. This barrier height change in turn can change the current (I_{GB}) between the gate region 102A and the bulk/substrate region 110A due to movement of charge carriers from the gate region 102A into the channel region 104A. A change in voltage at the source region 106A, drain region 108A, or gate region 104A relative to the gate region 102A (e.g., gate-to-source voltage V_{GS}) can thus influence the amplitude of a current output from the gate region 102A. In an alternative embodiment, the functions of the bulk/substrate region 110A and gate region 102A may be interchanged such that an output signal may be provided from the bulk/substrate region 110A. This is particularly applicable when the bulk is provided by a well implant, or the like and electrically isolated from other influences.

Because the current flow between gate region 102A and bulk/substrate region 110A is a strong nonlinear function of the average voltage in the channel region 104A while the average voltage in the channel region 104A is a weak non-linear function of the channel current (I_{DS}), an average channel current can be used as a control parameter for transfer gain coupling variations in the channel current to variations in the gate current (I_{GB}). This transfer gain control may be expressed as a differential equation:

d(I_{GB})/d(I_{DS})=AI_{DS}

where “A” is a constant representing a transfer characteristic of coupling variations in channel currents I_{DS} for variations in the gate-to-bulk current (I_{GB}).

FIG. 1B shows a device similar to FIG. 1A. However, in the FIG. 1B embodiment, the transistor device 100B is a p-channel structure. Transistor device 100B comprising a JFET device that may be used in a circuit providing an amplified signal output may include similar constituents as transistor device 100A. Such constituents may have the same first 3 digits, but end in a “B” instead of an “A” and may have an opposite conductivity type. P-type becomes n-type and n-type becomes p-type.

Transistor device 100B includes a gate region 102B, a drain region 108B, a source region 106B, and a channel region 104B formed on a substrate 110B. Substrate 110B and gate region 102B may be doped n-type. Drain region 108B, source region 106B, and channel region 104B may be doped p-type. In this way, transistor device 100B may be a p-channel JFET.

Referring now to FIG. 1C, yet another embodiment of a JFET device that may be used in a circuit providing an amplified signal output is set forth in a cross-sectional schematic diagram and given the general reference character 100C.

The transistor device 100C comprising an amplifier device may include similar constituents as transistor device 100A. Such constituents may have the same first 3 digits, but end in a “C” instead of an “A”.

Transistor device 100C may differ from transistor device 100A in that a second gate region 122C may be formed under the channel region 104C and on the substrate 110C. Transistor device 100C may also include isolation regions 126C formed by a shallow trench isolation (STI) method or the like.

Transistor device 100C may include a source terminal 116C, a drain terminal 114C, and a gate terminal 120C. The source terminal 116C and drain terminal 114C may be formed from n-type polysilicon, as just one example. The gate terminal 120C may be formed from p-type polysilicon. A diffusion step or the like may be used to form n-type source region 106C, n-type drain region 108C, and p-type gate region 102C by way of out diffusion from source terminal 116C, a drain terminal 114C, and a gate terminal 120C, respectively. The channel region 104C and substrate may be n-type and the gate region 122C may be p-type.

Referring now to FIG. 1D, yet another embodiment of a JFET device that may be used in a circuit providing an amplified signal output is set forth in a cross-sectional schematic diagram and given the general reference character 100D.

The transistor device 100D comprising an amplifier device may include similar constituents as transistor device 100B. Such constituents may have the same first 3 digits, but end in a “D” instead of an “B”.

Transistor device 100D may differ from transistor device 100B in that a second gate region 122D may be formed under the channel region 104D and on the substrate 110D. Transistor device 100D may also include isolation regions 126D formed by a shallow trench isolation (STI) method or the like.

Transistor device 100D may include a source terminal 116D, a drain terminal 114D, and a gate terminal 120D. The source terminal 116D and drain terminal 116D may be formed from p-type polysilicon, as just one example. The gate terminal 120D may be formed from n-type polysilicon. A diffusion step or the like may be used to form p-type source region 106D, p-type drain region 108D, and n-type gate region 102D by way of out diffusion from source terminal 116D, a drain terminal 114D, and a gate terminal 120D, respectively. The channel region 104D and substrate may be p-type and the gate region 122D may be n-type.

The exemplary transistor device as configured in FIGS. 1A, 1B, 1C, and 1D can be used in a variety of circuits to exploit the amplification function. One such example is an amplifier circuit as illustrated in FIG. 2A.

Referring now to FIG. 2A, a circuit schematic diagram of an amplifier circuit according to an embodiment is set forth and given the general reference character 200A. Amplifier circuit 200A includes a n-channel JFET transistor 202A.

The FIG. 2A amplifier circuit 200A includes a JFET transistor device 202A which can be configured as the JFET 100A of FIG. 1A or JFET 100C of FIG. 1C. The JFET 202A includes a gate region, a channel region, and a substrate (back gate) as previously described, wherein the current supplied across the channel region is substantially independent of the current supplied between the gate region and the bulk/substrate region.

Amplifier circuit 200A may include a n-channel JFET 202A having a first source/drain region receiving a time varying input signal signal in from an input terminal 204A. A first terminal of a bias current 206A may be connected to the first sour/drain region of n-channel JFET 202A. A second terminal of bias current 206A may be connected to a reference potential (ground). A second source/drain region of n-channel JFET 202A may be connected to a positive voltage 210A. A gate region may provide an amplified current output signal signal out at an output terminal 208A.

In the exemplary embodiment, a signal input terminal 204A may include a first contact connected to a channel region of JFET device 202A by way of a source/drain region. In this way a time varying signal, such as a current signal may be applied to the channel region. The time varying input signal can, for example, be applied to a source/drain region of JFET device 202A. The input signal signal in (a time varying input signal) can be provided have an offset voltage provided by a bias generator or the like.

The bias current 206A supplied in the exemplary circuit device 200A of FIG. 2A can be from any device acting as a current sink including, but not limited to a device described in FIGS. 1A to 1D, or any other suitable device.

A signal output terminal 208A may include an output contact for producing an amplified version of the time-varying input signal signal in (e.g., an amplified current output signal signal out). In addition, a signal output circuit may be interposed between the signal output terminal 208A and the gate region of JFET device 202A. The signal output circuit may include circuit components for modifying (e.g., filtering) the amplified time varying input signal signal in in any manner desired by the circuit designer.

In the exemplary embodiment of FIG. 2A, current gain may be controlled by the magnitude of the current supplied to the source region (106A or 106C). As such, a current mode gain element can be provided for inclusion in any circuit, including, but not limited to, analog system-on-a-chip circuitry or any other desired circuitry. Where relatively small voltages are used in the circuit design, a relatively small positive voltage level 210A may be applied to a contact to a channel region by way of a source/drain region.

In the exemplary embodiment of FIG. 2A, the bulk/back gate region may be connected to a reference potential, in this case a ground potential.

Referring now to FIG. 2B, a circuit schematic diagram of an amplifier circuit according to an embodiment is set forth and given the general reference character 200B. Amplifier circuit 200B may include a p-channel JFET device 202B. P-channel JFET device 202B may be a p-channel JFET device (100B and 100D) such as set forth in FIGS. 1B and 1D.

Amplifier circuit 200B can include a bias current 206B having a first terminal connected to a first source/drain terminal of p-channel JFET 202B and a second terminal connected to a reference potential (such as ground). An input terminal 204B may be connected to the first source/drain terminal of p-channel JFET 202B and may receive a time varying input signal signal in. An amplified current output signal signal out may be provided to an output terminal 208B from a gate region of p-channel JFET 202B. A second source/drain terminal of p-channel JFET 202B may receive a negative voltage potential 210B. A second gate region (i.e. a back gate or bulk/well region) may receive a reference potential (such as ground).

Similar to the amplifier circuit 200A of FIG. 2A, the amplifier circuit 200B of FIG. 2B may have a current gain controlled by a bias current supplied to the first source/drain region of p-channel JFET 202B.

Referring now to FIG. 3A, a circuit schematic diagram of a current amplifier circuit according to an embodiment is set forth and given the general reference character 300A.

The FIG. 3A amplifier circuit 300A includes a JFET transistor device 302 which can be configured as the JFET 100A of FIG. 1A or JFET 100C of FIG. 1C.

Amplifier circuit 300A may include an n-channel JFET 302 having a first source/drain region receiving an input signal current at an input terminal 308. A first terminal of a control current 306 may be connected to the first source/drain region of n-channel JFET 302. A second terminal of control current 306 may be connected to a reference potential (ground). A second source/drain region of n-channel JFET 302 may be connected to a positive voltage 310. A back gate region (bulk or well) may provide an amplified current output signal signal out at an output terminal 309. A front gate region may receive the reference potential (ground).

Referring now to FIG. 3B, a circuit schematic diagram of a current amplifier circuit according to an embodiment is set forth and given the general reference character 300B. Current amplifier circuit 300B may include a p-channel JFET device 322. P-channel JFET device 322 may be a p-channel JFET device (100B and 100D) such as set forth in FIGS. 1B and 1D.

Current amplifier circuit 300B can include a control current 326 having a first terminal connected to a first source/drain terminal of p-channel JFET 322 and a second terminal connected to a reference potential (such as ground). An input terminal 328 may be connected to the first source/drain terminal of p-channel JFET 322 and may receive an input current signal. An amplified current output signal may be provided to an output terminal 319 from a back gate region (well, bulk or substrate) of p-channel JFET 322. A second source/drain terminal of p-channel JFET 322 may receive a negative voltage potential 330. A front gate region may receive a reference potential (such as ground).

It should be understood in the above embodiments, a front gate region and a back gate region may be conceptualized as a first gate region and a second gate region interchangeably.

It should also be understood in the above embodiments that the source region and drain region of a JFET may be interchangeable and may be conceptualized as a first source/drain region and a second source/drain region.

Also, it should be understood that a positive power supply, negative power supply and a ground may be conceptualized as potentials.

Referring now to FIG. 4, a graph of representative signals of an exemplary amplifier circuit operated in a current mode as a current-mode amplifier according to an embodiment is set forth.

The graph of FIG. 4 shows the control current as a dashed line and an output current as a solid line.

Those skilled in the art will appreciated that the material selected for configuration of the device including the amplifier circuit can be of any known type. In alternate embodiments, strained silicon may optionally be used to form a layer portion on the substrate beneath the gate region in an effort to improved conductivity of the channel region. Referring to FIG. 1A, an optional strained silicon layer can be deposited on the substrate/bulk region 110A to form the channel region 104A. Such an option may enhance transistor switching speed in a reduced size transistor device.

The time varying input signal can, for example, range from the low audible range (e.g., <1 Hz) to microwave frequencies, or higher. In selecting a low end operating frequency, factors such as leakage rate on the gate can be taken into consideration. At the upper end of the frequency range, parasitic capacitance at the source and drain can be taken into consideration. The bias voltage applied to the channel can similarly be selected as a function of the desired operation and input signal frequency (e.g., the bias voltage can be within the range of 50 mV to 500 mV, or lesser or greater). For a lower frequency input audio signal, a bias voltage of, for example, 10-50 mV can be used, while a higher bias voltage of, for example, 500-600 mV can be used for a microwave input signal.

An exemplary method for controlling the gain of an output signal by means of a current mode input signal is also disclosed herein. In accordance with exemplary embodiments, the method can include establishing at least one of a transistor gate region and a substrate, and establishing a transistor device having a gate and a substrate. The method may include amplifying an input signal supplied to the transistor device to provide an amplified signal at an output of the transistor device.

In alternate embodiments, a circuit design can be established using a method which involves the transistor device as described herein. In such a method, a library of modular circuit components can be created, wherein at least one of the circuit components is a JFET device having a gate region, a channel region, and a substrate, wherein a current supplied across the channel region is substantially independent of a current supplied between the gate region and a bulk region of the substrate. In accordance with an exemplary embodiment, the circuit component can be selected for inclusion in an electrical circuit, such that a time varying input signal is applied to a first contact of the JFET device. A second contact of the JFET device may produce a signal output, which represents an amplified time varying input signal.

With the ability to use a JFET device as an amplifying device in an amplifier circuit as disclosed in the embodiments, digital and analog circuits may be provided on the same integrated circuit device by using JFET technology without the necessity of forming a hybrid technology in which one technology is used for digital circuits and another technology is used for the analog circuits. In this way, process steps may be minimized and manufacturing costs may be reduced.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is an inventive feature of the invention may include an elimination of an element.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. An amplifier circuit including a junction field effect transistor (JFET) device configured to amplify an input signal, comprising:
the JFET device including
a first source/drain region coupled to receive an input signal;
a second source/drain region coupled to receive a first potential; and
a first gate region coupled to provide an amplified output signal.

2. The amplifier circuit of claim 1, further including:
a current source having a first current source terminal coupled to the first source/drain region and a second current source terminal coupled to receive a second potential.

3. The amplifier circuit of claim 1, wherein:
the JFET device operates as a bipolar junction transistor (BJT).

4. The amplifier circuit of claim 1, wherein the JFET device further includes:
a second gate region coupled to receive a second potential.

5. The amplifier circuit of claim 4, wherein the second potential is a ground potential.

6. The amplifier circuit of claim 4, wherein the second gate region is a well region formed under a channel region of the JFET device.

7. The amplifier circuit of claim 4, wherein the first gate region is formed above a channel region and the second gate region is formed below a channel region.

8. The amplifier circuit of claim 4, wherein the first gate region is formed below a channel region and the second gate region is formed above the channel region.

9. The amplifier circuit of claim 1, wherein the first gate region is a well region.

10. The amplifier circuit of claim 1, wherein the JFET device is an n-channel JFET device.

11. The amplifier circuit of claim 10, wherein the JFET device further includes a region providing a second gate region coupled to receive a second potential and the first potential is positive with respect to the second potential.

12. The amplifier circuit of claim 1, wherein the JFET device is a p-channel JFET device.

13. The amplifier circuit of claim 10, further including a region providing a second gate region for the JFET device coupled to receive a second potential and the first potential is negative with respect to the second potential.

14. The amplifier circuit of claim 1, wherein the input signal is a time varying input signal.

15. The amplifier circuit of claim 1, wherein the input signal is an input signal current.

16. A method of amplifying an input signal, comprising:
receiving an input signal at a first source/drain region of a junction field effect transistor (JFET); and
providing an amplified output signal at a first gate region of the JFET.

17. The method of claim 16, further including the step of:
receiving a first potential at a second source/drain region of the JFET.

18. The method of claim 17, further including the step of:
receiving a second potential at a second gate region of the JFET.

19. The method of claim 18, wherein:
the first gate region is a well region formed under a channel region of the JFET and the second gate region is formed above the channel region of the JFET.

20. The method of claim 18, further including:
the second gate region is a well region formed under a channel region of the JFET and the first gate region is formed above the channel region of the JFET.

21. The method of claim 16, further including:
receiving a current at the first source/drain region.

22. The method of claim 16, wherein the first gate region is formed from a well region under a channel region of the JFET.

23. The method of claim 16, wherein:
the input signal is a input signal current.

24. The method of claim 16 wherein the JFET is a p-channel JFET.

25. The method of claim 16 wherein the JFET is an n-channel JFET.
